(19) United States
(12) Patent Application Publication
(10) Pub. No.: US 2019/0096844 A1
(43) Pub. Date: Mar. 28, 2019

(54) ANISOTROPIC CONDUCTIVE FILM AND MANUFACTURING METHOD THEREOF

(71) Applicant: DEXERIALS CORPORATION, Tokyo (JP)

(72) Inventors: Kenichi SARUYAMA, Utsunomiya-shi (JP); Yasushi AKUTSU, Utsunomiya-shi (JP)

(73) Assignee: DEXERIALS CORPORATION, Tokyo (JP)

(21) Appl. No.: 16/206,628

(22) Filed: Nov. 30, 2018

Related U.S. Application Data
(62) Division of application No. 14/904,519, filed on Jan. 12, 2016.

(30) Foreign Application Priority Data
Jul. 31, 2013 (JP) 2013-159441

(51) Int. Cl. H01L 23/00; H01R 4/04; H05K 3/32

(52) U.S. Cl. CPC H01L 24/29; H01L 2224/293; H01L 2924/00014; H01L 2224/2939; H01L 2224/29357; H01L 2224/271; H01L 2224/2711; H01L 2224/294; H01L 2224/29499; H01L 2224/29364; H01L 2224/29355; H01L 2224/29347; H01L 2224/29344; H01L 2224/29339; H01L 2224/2929; H01L 2224/2919; H01L 2224/29082; H01L 2224/29076; H01L 2224/29018; H01L 24/27; H01L 2224/27005; H05K 3/323; H01R 4/04

(57) ABSTRACT

An anisotropic conductive film 1A includes a conductive particle array layer 4 in which a plurality of conductive particles 2 are arrayed in a prescribed manner and held in an insulating resin layer The anisotropic conductive film 1A has a direction in which a thick distribution, around the individual conductive particle, of the insulating resin layer 3 holding the array of the conductive particles 2 is asymmetric with respect to the conductive particle 2. The direction in which the thickness distribution is asymmetric is aligned in the same direction in the plurality of conductive particles. When an electronic component is mounted using this anisotropic conductive film 1A, short circuits and conductive failure can be reduced.

This application is a Divisional of application Ser. No. 14/904,519, filed on Jan. 12, 2016, which is based on and claims priority under 35 U.S.C. 119 from Japanese Patent Application No. 2013-159441, filed Jul. 31, 2013, and the entire contents of which are incorporated herein by reference.

### TECHNICAL FIELD

The present invention relates to an anisotropic conductive film and a method of producing the same.

### BACKGROUND ART

An anisotropic conductive film is formed by dispersing conductive particles in an insulating adhesive and widely used for mounting an electronic component, such as an IC chip. Recent advances in the miniaturization of electronic apparatuses have also led to the miniaturization of mounting components. The shift to using narrow pitches is progressing and electrode pitches are, for example, narrowed to several tens of μm. When electrodes having a narrow pitch are connected via an anisotropic conductive film, short circuits caused by interconnected conductive particles between the electrodes and conductive failure caused by the absence of conductive particles between the electrodes tends to occur.

To solve such problems, arranging conductive particles regularly on an anisotropic conductive film has been considered. For example, a method of arranging conductive particles at a prescribed intercentral distance by filling the entire region of a stretchable film with conductive particles, fixing the conductive particles to the film, and then biaxially stretching the stretchable film (Patent Literature 1) and a method of arranging conductive particles by using a transfer die having a plenty of holes on the surface (Patent Literature 2) have been known.

### CITATION LIST

### Patent Literature

Patent Literature 1: Japanese Patent No. 4789738

Patent Literature 2: Japanese Patent Application Laid-Open No. 2010-33793

### SUMMARY OF INVENTION

### Technical Problem

However, in a conventional anisotropic conductive film having conductive particles regularly arrayed therein, when an electronic component is mounted using the anisotropic conductive film, an array of the conductive particles is irregularly disordered during thermocompression bonding. Thus, short circuits caused by interconnected conductive particles between the electrodes and conductive failure caused by the absence of conductive particles between the electrodes cannot be sufficiently eliminated.

In regards to these problems, a main object of the present invention is to reduce short circuits and conductive failure, which occur when an electronic component is mounted using an anisotropic conductive film having conductive particles regularly arrayed therein.

### Solution to Problem

The present inventors have found that, in an anisotropic conductive film holding conductive particles arrayed in a prescribed manner, a flow direction of the conductive particles, when an electronic component is mounted using the anisotropic conductive film, can be controlled by controlling a thickness distribution, around the conductive particles, of an insulating resin layer holding the conductive particles arrayed in a prescribed manner, whereby short circuits and conductive failure can be reduced, and that such a control of the thickness distribution of the insulating resin layer, in producing an anisotropic conductive film having conductive particles regularly arrayed therein by using a transfer die, can be performed by controlling a shape of a transfer die and filling the transfer die with the insulating resin, thereby holding the conductive particles in the insulating resin. The present invention has thus been achieved.

That is, the present invention provides an anisotropic conductive film including a conductive particle array layer in which a plurality of conductive particles are arrayed in a prescribed manner and held in an insulating resin layer, the anisotropic conductive film having a direction in which a thickness distribution, around the individual conductive particle, of the insulating resin layer holding the array of the conductive particles is asymmetric with respect to the conductive particle.

Further, the present invention provides a method of producing the above-mentioned anisotropic conductive film, including the steps of:

filling a transfer die having a plurality of openings on a surface thereof with conductive particles;

laminating an insulating resin on the conductive particle and

forming a conductive particle array layer, in which a plurality of the conductive particles are arrayed in a prescribed manner and held in an insulating resin layer, the conductive particle array layer being transferred from the transfer die to the insulating resin layer,

wherein the transfer die used has a direction in which a depth distribution in the individual opening is asymmetric with respect to a vertical line passing through a center a deepest part of the opening.

Further, the present invention provides a connection structure connecting a first electronic component and a second electronic component via an anisotropic conductive connection using the above-mentioned anisotropic conductive film.

### Advantageous Effects of Invention

According to an anisotropic conductive film of the present invention, there is a direction in which a thickness distribution, around an individual conductive particle, of an insulating resin layer holding an array of the conductive particles is asymmetric with respect to the conductive particle. Thus, a flow direction of the conductive particles, when an electronic component is mounted using the anisotropic conductive film, depends on a direction in which a resin amount, around the conductive particles, of the insulating resin layer holding an array of the conductive particles is less. Therefore, when an electronic component is mounted using the anisotropic conductive film, the flow directions of the conductive particles are not biased to a specific site. Thus, short circuits caused by interconnected conductive particles between the electrodes and conductive failure caused by the absence of the conductive particles between the electrodes can be reduced. As such, the connection structure of the present invention, prepared by using the anisotropic conductive film, causes less short circuits and conductive failure and is excellent in connection reliability.

Further, when the anisotropic conductive film of the present invention is produced by the method of producing the anisotropic conductive film of the present invention, a transfer die used includes openings having directivity in a depth distribution thereof, making it easy to fill the openings of the transfer die with conductive particles. Thus, it is possible to prevent aggregation and lacking of the conductive particles in the openings when the openings are filled with the conductive particles. Thus, defects in an array of conductive particles occurring in the anisotropic conductive film can be prevented. As a result, according to the anisotropic conductive film obtained by this method, short circuits and conductive failure occurring when an electronic component is mounted can be further reduced.

Further, according to the method for producing the anisotropic conductive film of the present invention, after a conductive particle array layer is formed by using a transfer die, a work for releasing the conductive particle array layer from the transfer die is facilitated. Thus, productivity of the anisotropic conductive film is improved.

### BRIEF DESCRIPTION OF DRAWINGS

FIG. 1A is a plan view of an anisotropic conductive film 1A according to one embodiment of the present invention.

FIG. 1B is a cross-sectional view of the anisotropic conductive film 1A according to one embodiment of the present invention.

FIG. 1C is a cross-sectional view of the anisotropic conductive film 1A according to one embodiment of the present invention.

FIG. 2A is a perspective view of a transfer die 10A used for producing the anisotropic conductive film 1A.

FIG. 2B is a top view of the transfer die 10A used for producing the anisotropic conductive film 1A,

FIG. 2C is a cross-sectional view of the transfer die 10A used for producing the anisotropic conductive film 1A.

FIG. 3A is a top view of the transfer die 10A filled with conductive particles.

FIG. 3B is a cross-sectional view of the transfer die 10A filled with the conductive particles.

FIG. 4A is an explanatory diagram illustrating a step of producing the anisotropic conductive film 1A.

FIG. 4B is an explanatory diagram illustrating a step of producing the anisotropic conductive film 1A.

FIG. 4C is an explanatory diagram illustrating a step of producing the anisotropic conductive film 1A.

FIG. 4D is an explanatory diagram illustrating a step of producing the anisotropic conductive film 1A.

FIG. 4E is an explanatory diagram illustrating a step of producing the anisotropic conductive film 1A.

FIG. 4F is an explanatory diagram illustrating a step of producing the anisotropic conductive film 1A.

FIG. 4G is an explanatory diagram illustrating a step of producing the anisotropic conductive film 1A.

FIG. 5A is an explanatory diagram illustrating a step of producing the anisotropic conductive film 1A.

FIG. 5B is an explanatory diagram illustrating a step of producing the anisotropic conductive film 1A.

FIG. 5C is an explanatory diagram illustrating a step of producing the anisotropic conductive film 1A.

FIG. 5D is an explanatory diagram illustrating a step of producing the anisotropic conductive film 1A.

FIG. 5E is an explanatory diagram illustrating a step of producing the anisotropic conductive film 1A.

FIG. 6A is an explanatory diagram illustrating a step of producing the anisotropic conductive film 1A.

FIG. 6B is an explanatory diagram illustrating a step of producing the anisotropic conductive film 1A.

FIG. 6C is an explanatory diagram illustrating a step of producing the anisotropic conductive film 1A.

FIG. 6D is an explanatory diagram illustrating a step of producing the anisotropic conductive film 1A.

FIG. 6E is an explanatory diagram illustrating a step of producing the anisotropic conductive film 1A.

FIG. 6F is an explanatory diagram illustrating a step of producing the anisotropic conductive film 1A.

FIG. 6G is an explanatory diagram illustrating a step of producing the anisotropic conductive film 1A.

FIG. 7A is a plan view of an anisotropic conductive film 1A′ according to one embodiment of the present invention.

FIG. 7B is a cross-sectional view of the anisotropic conductive film 1A′ according to one embodiment of the present invention.

FIG. 7C is a cross-sectional view of the anisotropic conductive film 1A′ according to one embodiment of the present invention.

FIG. 8 is a plan view of an anisotropic conductive film 1A′ according to one embodiment of the present invention.

FIG. 9A is a cross-sectional view of a transfer die 103 filled with conductive particles.

FIG. 9B is a cross-sectional view of an anisotropic conductive film 13 obtained by using the transfer die 103.

FIG. 10A is a cross-sectional view of a transfer die 10C filled with conductive particles.

FIG. 10B is a cross-sectional view of an anisotropic conductive film 1C obtained by using the transfer die 10C.

FIG. 11A is a cross-sectional view of a transfer die 10D filled with conductive particles.

FIG. 11B is a cross-sectional view of an anisotropic conductive film 1D obtained by using the transfer die 103.

FIG. 12A is a cross-sectional view of a transfer die 10E filled with conductive particles.

FIG. 12B is a cross-sectional view of an anisotropic conductive film 1E obtained by using the transfer die 10E.

FIG. 13A is a cross-sectional view of a transfer die 10X filled with conductive particles, used in Comparative Example.

FIG. 13B is a cross-sectional view of an anisotropic conductive film 1X obtained by using the transfer die 10X.

FIG. 14 is an explanatory diagram illustrating a method of evaluating adhesion strength of an anisotropic conductive connection between a glass substrate and an IC chip.

### DESCRIPTION OF EMBODIMENTS

Hereinafter, the present invention will be described in detail with reference to the drawings. Tt is noted that, in the drawings, the same reference numerals denote the same or similar constituent elements.

### (1) Configuration of Anisotropic Conductive Film

### (1-1) Overall Configuration

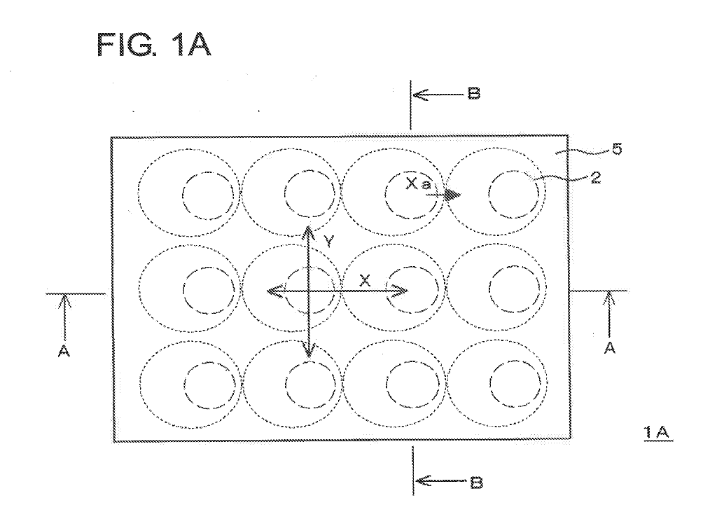

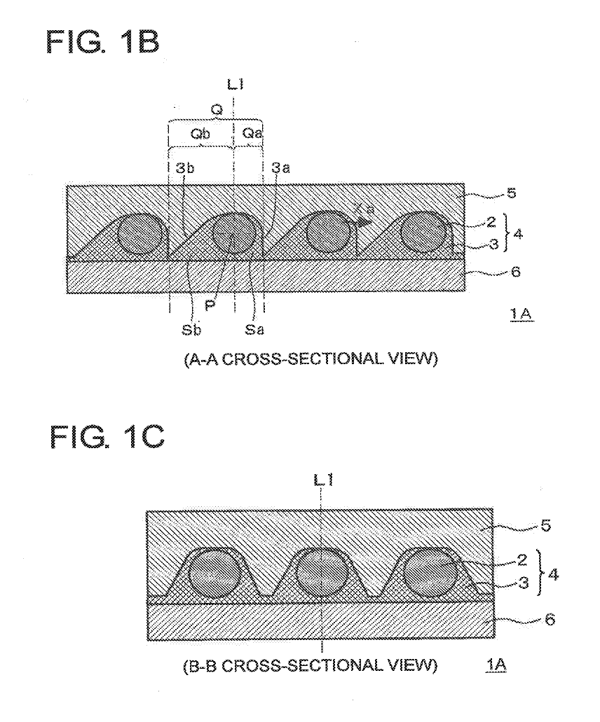

FIG. 1A is a plan view of an anisotropic conductive film 1A according to one embodiment of the present invention. FIG. 1B is a cross-sectional view taken along the line A-A of FIG. 1A, while FIG. 1C is a cross-sectional view taken along the line B-B of FIG. 1A.

As shown in the drawings, the anisotropic conductive film 1A includes a conductive particle array layer 4, in which a plurality of conductive particles 2 are directly held in an insulating resin layer 3, and is characterized in that the insulating resin layer 3 has a specific thickness distribution around the individual conductive particle 2, as described below. The conductive particle array layer 4 has a flat surface on one side and an irregular surface on the other side. A second insulating resin layer 5 is laminated on the irregular surface thereof while a third insulating resin layer 6 is laminated on the flat surface thereof. It is noted that, in the present invention, the second insulating resin layer 5 and the third insulating resin layer 6 are each optionally provided to improve adhesive properties of an anisotropic conductive connection between electronic components.

### (1-2) Conductive Particle Array Layer

In the conductive particle array layer 4, a plurality of the conductive particles 2 are arranged in a tetragonal lattice pattern as a single layer. Further, the individual conductive particles 2 are each held by the insulating resin layer 3 in a convex part of the conductive particle array layer 4, and the insulating resin layer 3 has a truncated oblique cone shape with nearly round corners around the individual conductive particle 2.

It is noted that, in the present invention, an array of the conductive particles 2 is not limited to the tetragonal lattice pattern. For example, the array may be in a hexagonal lattice pattern. The number of the conductive particles held in the insulating resin layer 3 in a single convex part of the conductive particle array layer 4 is not limited to one and may be plural.

Further, in the present invention, the shape of the insulating ruin layer 3 forming the convex parts of the conductive particle array layer 4 is not limited to the truncated oblique cone shape, and may be, for example, truncated pyramid shapes, such as a truncated oblique quadrangular pyramid shape.

The anisotropic conductive film 1A has a direction X, in which a thickness distribution of the insulating resin layer 3 is bilaterally asymmetric with respect to a central axis L1 of the conductive particle 2 (a central axis in a thickness direction of the anisotropic conductive film 1A), and the direction X is aligned in the same direction in every conductive particle 2.

Specifically, in an A-A cross section (FIG. 1B) of the anisotropic conductive film 1A when the anisotropic conductive film 1A is cut in the direction X passing through a center P of a given conductive particle 2, the area of the insulating resin layer 3 in a region Q surrounding the individual conductive particle 2 is configured such that an area Sₐ on one side Qₐ of the given conductive particle 2 is smaller than an area S_{b} on the other side Q_{b}. Here, the insulating resin layer 3 in the region Q surrounding the individual conductive particle 2 refers to a convex region of the insulating resin layer 3 holding the individual conductive particle 2 in the cross section, that is, a range, in the cross section, from the thinnest part in a layer thickness of the insulating resin layer 3 (a distance between a top surface of the convex region and a flat bottom surface of the insulating resin layer 3) between the given conductive particle 2 and its adjacent conductive particle 2 on one side to the thinnest part in a layer thickness of the insulating resin layer 3 between the given conductive particle 2 and its adjacent. conductive particle 2 on the other

Further, in this cross section, a side surface 3ₐ on the one side Qₐ of the conductive particle 2 is formed into a precipitous cliff shape along a thickness direction of the anisotropic conductive film 1A, while a side surface 3_{b} on the other side Q_{b} is inclined with respect to the thickness direction of the anisotropic conductive film 1A more than the side surface 3ₐ on the one side Qₐ.

As described above, the anisotropic conductive film 1A has the direction X in which the thickness distribution of the insulating resin layer 3 around the individual conductive particle 2 is asymmetric with respect to the central axis L1 of the conductive particle 2. In the cross section in the direction X (FIG. 1B, the area Sₐ on the one side Qₐ of the conductive particles 2 is smaller than the area S_{b} on the other side Q_{b}, thus there is less amount of a resin in the insulating resin layer 3 holding the conductive particle 2 on the one side Qₐ than that on the other side Q_{b}. Thus, when an electronic component is mounted by using the anisotropic conductive film 1A, during a heating and pressurizing process, the conductive particles 2 easily flow in a direction Xₐ having a less amount of the resin in the insulating resin layer 3 holding the conductive particles 2 (FIG. 1A). Therefore, this can prevent the conductive particles from flowing irregularly and accumulating on a specific site, which is otherwise caused by heating and pressurizing at mounting. As a result, short circuits caused by interconnected conductive particles between the electrodes and conductive failure caused by the absence of the conductive particles between the electrodes can be reduced.

Furthermore, since the insulating resin layer has a thickness distribution described above, a resin layer forming an anisotropic conductive film surface has surface irregularities. As a result, the anisotropic conductive film can be expected to have higher tackiness and better adhesive properties as compared with a case where the film is formed by a resin layer having a flat surface.

It is noted that the anisotropic conductive film of the present invention may have at least one direction in which the thickness distribution of the insulating resin layer 3 around the individual conductive particle 2 is asymmetric with respect to the conductive particle 2, and, in other directions, the thickness distribution of the insulating resin layer 3 around the conductive particle 2 may be symmetric with respect to the conductive particle 2. For example, in the B-B cross section of the above-mentioned anisotropic conductive film 1A in a Y direction perpendicular to an X direction, as shown in FIG. 1C, a thickness distribution of the insulating resin layer 3 around the conductive particles 2 is symmetric with respect to the central axis L1 of the conductive particle 2.

### (1-3) Conductive Particles

In the anisotropic conductive film 1A, the conductive particles 2 may be appropriately selected from conductive particles used in conventionally known anisotropic conductive films. Examples thereof may include particles of metal, such as nickel, cobalt, silver, copper, gold, and palladium, and metal-coated resin particles. Two or more kinds thereof may be used in combination.

When the average particle diameter of the conductive particles 2 is too small, variations in height of wirings performing an anisotropic conductive connection cannot be absorbed, and conduction resistance tends to increase. When it is too large, short circuits tend to occur. Therefore, it is preferably 1 to 10 μm and more preferably 2 to 6 μm.

When the amount of the conductive particles 2 in the anisotropic conductive film 1A is too small, a particle capturing efficiency decreases thereby making an anisotropic conductive connection difficult. When it is too large, there is a concern in which short circuits may occur. Therefore, it is preferably 50 to 50,000 particles per square millimeter, more preferably 200 to 40,000 particles, and further preferably 400 to 30,000 particles.

### (1-4) Insulating Resin Layer

As the insulating resin layer 3 holding the conductive particles 2, a known insulating resin layer may be appropriately selected. For example, a photo-radical polymerizable resin layer containing an acrylate compound and a photo-radical polymerization initiator, a thermal-radical polymerizable resin layer containing an acrylate compound and a thermal-radical polymerization initiator, a thermal-cationic polymerizable resin layer containing an epoxy compound and a thermal-cationic polymerization initiator, or a thermal-anionic polymerizable resin layer containing an epoxy compound and a thermal-anionic polymerization initiator may be used. Further, these resin layers may each be polymerized in advance as needed.

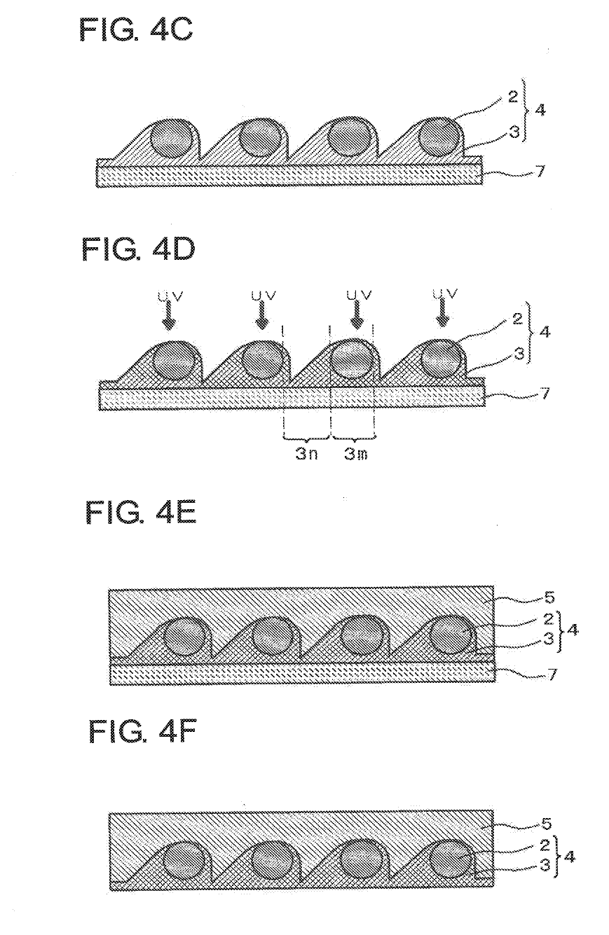

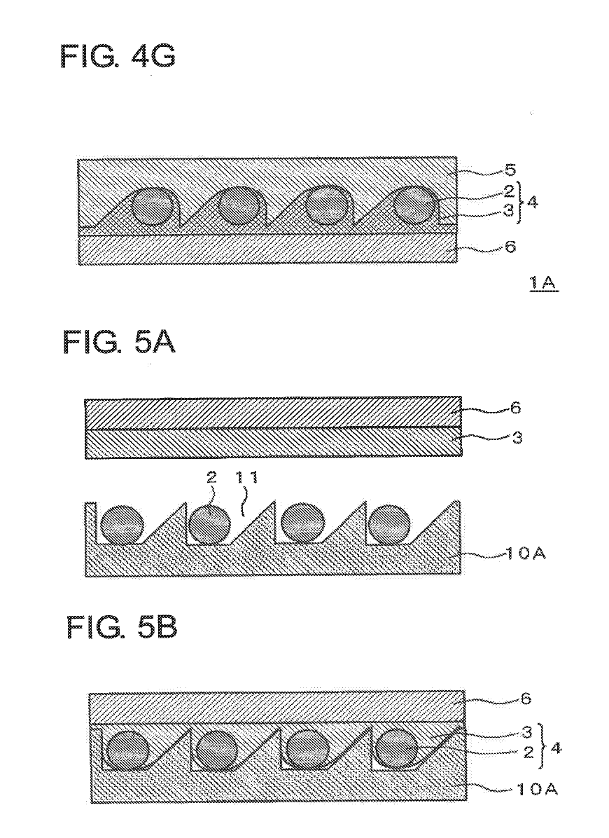

Of these, as the insulating resin layer 3, a photo-radical polymerizable resin layer containing an acrylate compound and a photo-radical polymerization initiator is preferably adopted. By irradiating the photo-radical polymerizable resin layer with ultraviolet rays to induce photo-radical polymerization, the conductive particle array layer 4 in which the conductive particles 2 are fixed to the insulating resin layer 3 can be formed. In this case, as described below, when the photo-radical polymerizable resin layer is irradiated with ultraviolet rays from a side of the conductive particles 2 to induce photo-radical polymerization before formation of the second insulating resin layer 5, as shown in FIG. 4D, a curing rate of the insulating resin layer 3 in a region located between the flat surface of the conductive particle array layer 4 and the conductive particles 2 can be made lower than that of the insulating resin layer 3 in a region 3ₙ located between the conductive particles 2 adjacent to each other. Therefore, in the insulating resin layer 3, a minimum melt viscosity in the region 3ₘ located directly below the conductive particles 2, having a low curing rate, can be made lower than that in the region 3ₙ located around the conductive particles 2, having a high curing rate. Thus, during an anisotropic conductive connection, the conductive particles 2 are easily pushed in without causing positional displacement in a horizontal direction. As a result, the particle capturing efficiency can be improved, the conduction resistance can be decreased, and favorable conduction reliability can be achieved.

Here, the curing rate represents a numerical value defined as a decrease ratio of a functional group (for example, a vinyl group) contributing to polymerization. Specifically, when the existing amount of a vinyl group after curing is 20% of that before curing, the curing rate is calculated as 80%. The existing amount of a vinyl group can be measured by analysis of a characteristic absorption of a vinyl group in infrared absorption spectrum. The curing rate of the insulating resin layer 3 in the region 3ₘ having a low curing rate is preferably 40 to 80%, and the curing rate in the region 3ₙ having a high curing rate is preferably 70 to 100%.

The minimum melt viscosity of the insulating resin layer 3 can be measured by a rheometer. When this value is too low, the particle capturing efficiency tends to decrease, while when the value is too high, the conduction resistance tends to increase. Therefore, the value is preferably 100 to 100,000 mPa·s and more preferably 500 to 50,000 mPa·s.

Further it is preferable that the minimum melt viscosity of the insulating resin layer 3 is higher than that of either of the second insulating resin layer 5 and the third insulating resin layer 6. Specifically, when the numerical value of [minimum melt viscosity (mPa·s) of insulating resin layer 3]/[minimum melt viscosity (mPa·s) of second insulating resin layer 5 or third insulating resin layer 6] is too low, the particle capturing efficiency tends to decrease and a probability of occurrence of short circuits tends to increase. On the other hand, when the value is too high, the conduction reliability tends to decrease. Therefore, the numerical value of [minimum melt viscosity (mPa·s) of insulating resin layer 3]/[minimum melt viscosity (mPa·s) of second insulating resin layer 5 or third insulating resin layer 6] is preferably 1 to 1,000 and more preferably 4 to 400.

Further, when the minimum melt viscosities of the second insulating resin layer 5 and the third insulating resin layer 6 are too low, a resin tends to be squeezed out during formation of a reel, and when they are too high, a conduction resistance value tends to increase. Therefore, they are preferably 0.1 to 10,000 mPa·s and more preferably 1 to 1,000 mPa·s.

As an acrylate compound used in the insulating resin layer 3, a conventionally known radically polymerizable acrylate may be used. For example, a monofunctional (meth)acrylate (herein, (meth)acrylate includes acrylate and methacrylate) and a polyfunctional, i.e., bifunctional or more, (meth)acrylate can be used. Further, in the present invention, it is preferable that a polyfunctional (meth)acrylate is used at least as a part of an acrylic monomer in order to make the insulating resin layer 3 thermocurable.

Examples of the monofunctional (meth)acrylate may include methyl (meth)acrylate, ethyl (meth)acrylate, n-propyl (meth)acrylate, i-propyl (meth)acrylate, n-butyl (meth)acrylate, i-butyl (meth)acrylate, t-butyl (meth)acrylate, 2-methylbutyl (meth)acrylate, n-pentyl (meth)acrylate, n-hexyl (meth)acrylate, n-heptyl (meth)acrylate, methylhexyl (meth)acrylate, 2-ethylhexyl (meth)acrylate, 2-butylhexyl (meth)acrylate, isooctyl (meth)acrylate, isopentyl (meth)acrylate, isononyl (meth)acrylate, isodecyl (meth)acrylate, isobornyl (meth)acrylate, cyclohexyl (meth)acrylate, benzyl (meth)acrylate, phenoxy (meth)acrylate, n-nonyl (meth)acrylate, n-decyl (meth)acrylate, lauryl (meth)acrylate, hexadecyl (meth)acrylate, stearyl (meth)acrylate, and morpholin-4-yl (meth)acrylate. Examples of the bifunctional (meth)acrylate may include bisphenol F-EO-modified di(meth)acrylate, bisphenol A-EO-modified di(meth)acrylate, polypropylene glycol di(meth)acrylate, polyethylene glycol (meth)acrylate, tricyclodecane dimethylol di(meth)acrylate, and dicyclopentadiene (meth)acrylate. Examples of a trifunctional (meth)acrylate may include trimethylolpropane tri(meth)acrylate, trimethylolpropane PO-modified (meth)acrylate, and isocyanuric acid EO-modified tri(meth)acrylate. Examples of a tetrafunctional or more functional (meth)acrylate may include dipentaerythritol penta(meth)acrylate, pentaerythritol hexa(meth)acrylate, pentaerythritol tetra(meth)acrylate, and di-trimethylolpropane tetraacrylate. In addition, a polyfunctional urethane (meth)acrylate may also be used. Specific examples thereof may include M1100, M1200, M1210, and M1600 (all available from Toagosei Co., Ltd.), and AH-600 and AT-600 (all available from Kyoeisha Chemical Co., Ltd.).

When the content of the acrylate compound in the insulating resin layer 3 is too low, generating a difference in the minimum melt viscosity between the insulating resin layer 3 and the second insulating layer 5 tends to become harder. When it is too high, curing shrinkage tends to be larger and the workability tends to decrease. Therefore, the content is preferably 2 to 70% by mass and more preferably 10 to 50% by mass.

The photo-radical polymerization initiator used may be appropriately selected from known photo-radical polymerization initiators. Examples thereof may include an acetophenone-based photopolymerization initiator, a benzylketal-based photopolymerization initiator, and a phosphorus-based photopolymerization initiator. Specific examples of the acetophenone-based photopolymerization initiator may include 2-hydroxy-2-cyclohexylacetophenone (IRGACURE 184, available from BASF Japan Ltd.), α-hydroxy-α,α′-dimethylacetophenone (DAROCUR 1173, available from BASF Japan. Ltd.), 2,2-dimethoxy-2-phenylacetophenone (IRGACURE 651, available from BASF Japan Ltd.), 4-(2-hydroxyethoxy)phenyl (2-hydroxy-2-propyl) ketone (DAROCUR 2959, available from BASF Japan Ltd.), and 2-hydroxy-1-{4-{4-[2-hydroxy-2-methyl-propionyl]-benzyl}phenyl}-2-methyl-propan-2-one (IRGACURE 127, available from BASF Japan Ltd.). Examples of the benzylketal-based photopolymerization initiator may include benzophenone, fluorenone, dibenzosuberone, 4-aminobenzophenone, 4,4′-diaminobenzophenone, 4-hydroxybenzophenone, 4-chlorobenzophenone, and 4,4′-dichloroben phenone. Further, 2-benzyl-2-dimethylamino-1-(4-morpholinophenyl)-butanone-1 (IRGACURE 369, available from BASF Japan Ltd.) may also be used. Examples of the phosphorus-based photopolymerization initiator may include bis(2,4,6-trimethylbenzoyl)-phenylphosphine oxide (IRGACURE 819, available from BASF Japan Ltd.) and 2,4,6-trimethylbenzoyl-diphenylphosphine oxide (DAROCUR TPO, available from BASF Japan Ltd.).

When the amount of the photo-radical polymerization initiator used is too small with respect to 100 parts by mass of the acrylate compound, photo-radical polymerization tends not to proceed sufficiently. When is too large, there is a concern in which a decrease in rigidity may be caused. Therefore, it is preferably 0.1 to 25 parts by mass and more preferably 0.5 to 15 parts mass.

When the insulating resin layer 3 is constituted by a thermal-radical polymerizabie resin layer containing an acrylate compound and a thermal-radical polymerization initiator, chemical compounds mentioned earlier can be applied as an acrylate compound. Further, examples of the thermal-radical polymerization initiator may include an organic peroxide and an azo-based compound. An organic peroxide can be preferably used since there is a concern in which an azo-based compound is decomposed during a polymerization reaction thereby generating nitrogen gas, and as a result, air bubbles are mixed into a polymer. Examples of the organic peroxide may include Perhexa 3M, PEROYL TCP, and PEROYL L, all available from NOF Corp.

Examples of the organic peroxide may include methyl ethyl ketone peroxide, cyclohexanone peroxide, methyl cyclohexanone peroxide, acetylacetone peroxide, 1,1-bis(tert-buty peroxy)3,3,5-trimethyl cyclohexane, 1,1-bis(tert-butylperoxy)cyclohexane, 1,1-bis(tert-hexylperoxy)3,3,5-trimethyl cyclohexane, 1,1-bis(tert-hexylperoxy)cyclohexane, 1,1-bis(tert-butylperoxy)cyclododecane, isobutyl peroxide, lauroyl peroxide, succinic acid peroxide, 3,5,5-trimethyl hexnoyl peroxide, benzoyl peroxide, octanoyl peroxide, stearoyl peroxide, diisopropyl peroxydicarbonate, dinormal propyl peroxydicarbonate, di-2-ethylhexyl peroxydicarbonate, di-2-ethoxyethyl peroxydicarbonate, di-2-methoxybutyl peroxydicarbonate, bis-(4-tert-butylcyclohexyl)peroxydicarbonate, (α,α-bis-neodecanoylperoxy)diisopropylbenzene, peroxyneodecanoic acid cumyl ester, peroxyneodecanoic acid octyl ester, peroxyneodecanoic acid hexyl ester, peroxyneodecanoic acid tert-butyl ester, peroxypivalic acid tert-hexyl ester, peroxypivalic acid tert-butyl ester, 2,5-dimethyl-2,5-bis(2-ethylhexanoylperoxy)hexane, 1,1,3,3-tetramethylbutylperoxy-2-ethylhexanoate, peroxy-2-ethylhexanoic acid tert-hexyl ester, peroxy-2-ethylhexanoic acid tert-butyl ester, peroxy-3-methylpropionic acid tent-butyl ester, peroxylauric acid tert-butyl ester, tert-butyl peroxy-3,5,5-trimethyl hexanoate, tert-hexylperoxy isopropyl monocarbonate, tert-butylperoxy isopropyl carbonate, 2,5-dimethyl-2,5-bis(benzoylperoxy)hexane, peracetic acid tert-butyl ester, perbenzoic acid tert-hexyl aster, and perbenzoic acid tert-butyl ester. An organic peroxide may be added with a reducing agent and used as a redox polymerization initiator.

Examples of the azo-based compound may include 1,1-azobis(cyclohexane-1-carbonitrile), 2,2′-azobis(2-methyl-butyronitrile), 2,2′-azobisbutyronitrile, 2,2′-azobis(2,4-dimethyl-valeronitrile), 2,2′-azobis(2,4-dimethyl-4-methoxyvaleronitrile), 2,2′-azobis(2-amidino-propane) hydrochloride, 2,2′-azobis(2-(5-methyl-2-imidazolin-2-yl)propane] hydrochloride, 2,2′-azobis[2-(2-imidazolin-2-yl)propane] hydrochloride, 2,2′-azobis[2-(5-methyl-2-imidazolin-2-yl)propane], 2,2′-azobis[2-methyl-N-(1,1-bis(2-hydroxymethyl)-2-hyd-oxyethyl)propionamide], 2,2′-azobis[2-methyl-N-(2-hydroxyethyl)propionamide], 2,2′-azobis(2-methyl-propionamide) dihydrate, 4,4′-azobis(4-cyano-valeric acid), 2,2′-azobis(2-hydroxymethylpropiononitrile), 2,2′-azobis(2-methylpropionic acid) dimethyl ester (dimethyl 2,2′-azobis (2-methylpropionate)), and cyano-2-propyl azoformaide.

When the amount of the thermal-radical polymerization initiator used is too small, thermal-radical polymerization tends not to proceed sufficiently, while when it is too large, there is a concern in which a decrease in rigidity may be caused. Therefore, the amount is preferably 0.1 to 25 parts by mass and more preferably 0.5 to 15 parts by mass, with respect to 100 parts by mass of the acrylate compound.

When the insulating resin layer 3 is constituted by a thermal-cationic polymerizable resin layer containing an epoxy compound and a thermal-cationic polymerization initiator, or by a thermal-anionic polymerizable resin layer containing an epoxy compound and a thermal-anionic polymerization initiator, examples of the epoxy compound may preferably include a compound or a resin having two or more epoxy groups in its molecule. These may be liquid or solid. Specific examples thereof may include glycidyl ethers obtained by reacting epichlorohydrin with a polyhydric phenol, such as bisphenol A, bisphenol F, bisphenol S, hexahydrobisphenol A, tetramethylbisphenol A, diallylbisphenol A, hydroquinone, catechol, resorcin, cresol, tetrabromobisphenol A, trihydroxybiphenyl, nophenone, bisresorcinol, bisphenol hexafluoroacetone, tetramethylbisphenol A, tetramethylbisphenol F, tris(hydroxyphenyl)methane, bixylenol, phenol novolak, and cresol novolak; polyglycidyl ethers obtained by reacting epichlorohydrin with an aliphatic polyhydric alcohol, such as glycerol, neopentyl glycol, ethylene glycol, propylene glycol, butylene glycol, hexylene glycol, polyethylene glycol, and polypropylene glycol; glycidyl ether esters obtained by reacting epichlorohydrin with a hydroxycarboxylic acid, such as p-oxybenzoic acid and β-oxynaphthoic acid; polyglycidyl esters obtained from polycarboxylic acid, such as phthalic acid, methylphthalic acid, isophthalic acid, terephthalic acid, tetrahydrophthalic acid, hexahydrophthalic acid, endomethylene tetrahydrophthalic acid, endomethylene hexahydrophthalic acid, trimellitic acid, and polymerized fatty acids; glycidylaminoglycidyl ethers obtained from aminophenol and aminoalkylphenol; glycidylaminoglycidyl esters obtained from aminobenzoic acid; glycidylamines obtained from aniline, toluidine, tribromoaniline, xylylenediamine, diaminocyclohexane, bisaminomethylcyclohexane, 4,4′-diaminodiphenylmethane, and 4,4′-diaminodiphenyl sulfone; and known epoxy resins, such as an epoxidized polyolefin. Further, alicyclic epoxy compounds such as 3,4-epoxycyclohexenylmethyl-3′,4′-epoxycyclohexene carboxylate may also be used.

The thermal-cationic polymerization initiator generates, by heat, an acid capable of performing cationic polymerization of a cationically polymerizable compound. As the thermal-cationic polymerization initiator, any known thermal-cationic polymerization initiator for an epoxy compound may be used. For example, known iodonium salts, sulfonium salts, phosphonium salts, ferrocenes and the like may be used. Aromatic sulfonium salts exhibiting favorable latency with temperature may preferably be used. Preferable examples of the thermal-cationic polymerization initiator may include diphenyliodonium hexafluoroantimonate, diphenyliodonium hexafluorophosphate, diphenyliodonium hexafluoroborate, triphenylsulfonium hexafluoroantimonate, triphenylsulfonium hexafluorophosphate, and triphenylsulfonium hexafluoroborate. Specific examples thereof may include SP-150, SP-170, CP-66, and CP-77 available from ADEKA Corp.; CI-2855 and CI-2639 available from Nippon Soda Co., Ltd.; SAN-AID SI-60 and SI-80 available from Sanshin Chemical Industry Co., Ltd.; and CYRACURE-UVI-6990 and UVI-6974 available from Union Carbide Corp.

When the added amount of the thermal-cationic polymerization initiator is too small, thermal-cationic polymerization tends not to proceed sufficiently, while when itis too large, there is a concern in which a decrease in rigidity may be caused. Therefore, the amount is preferably 0.1 to 25 parts by mass and more preferably 0.5 to 15 parts by mass, with respect to 100 parts by mass of the epoxy compound.

The thermal-anionic polymerization initiator generates, by heat, a base capable of performing anionic polymerization of an anionically polymerizable compound. As the thermal-anionic polymerization initiator, any known thermal-anionic polymerization initiator for an epoxy compound may be used. For example, aliphatic amine compounds, aromatic amine compounds, secondary or tertiary amine compounds, imidazole compounds, polymercaptan compounds, boron trifluoride-amine complexes, dicyandiamide, organic acid hydrazide, and the like may be used. Encapsulated imidazole compounds exhibiting favorable latency with temperature may be preferably used.

When the added amount of the thermal-anionic polymerization initiator is too small, curing tends to be incomplete, while when it is too large, a product life tends to decrease. Therefore, the amount is preferably 0.1 to 40 parts by mass and more preferably 0.5 to 20 parts by mass, with respect to 100 parts by mass of the epoxy compound.

On the other hand, the second insulating resin layer 5 and the third insulating resin layer 6 can each be formed from a resin appropriately selected from known insulating resins. They may also be formed from the same material as the insulating resin layer 3.

The minimum melt viscosity of the insulating resin layer 3 may be equal to, lower than, or higher than those of the second insulating resin layer 5 and the third insulating resin layer 6. However, when the second insulating resin layer 5 and the third insulating resin layer 6 are formed from the same material as the insulating resin layer 3, the minimum melt viscosity of the insulating resin layer 3 is preferably higher than those of the second insulating resin layer 5 and the third insulating resin layer 6.

When the thickness of the second insulating resin layer 5 is too thin, there is a concern in which conductive failure may occur due to an insufficient filling of the resin. When it is too thick, there is a concern in which the resin is squeezed out during compression bonding and a compression-bonding device may be contaminated. Therefore, the thickness is 40 μm or less, preferably 5 to 20 μm, and more preferably 8 to 15 μm. When the thickness of the third insulating resin layer 6 is too thin, there is a concern in which adhesion failure may be caused when the third insulating resin layer 6 is temporarily adhered to a second electronic component. When it is too thick, the conduction resistance tends to increase. Therefore, the thickness is preferably 0.5 to 6 μm and more preferably 1 to 5 μm.

When an anisotropic conductive connection is achieved using the anisotropic conductive film 1A, between the second insulating resin layer 5 (the insulating resin laminated on the irregular surface of the conductive particle array layer 4) and the third insulating resin layer 6 (the insulating resin laminated on the flat surface of the conductive particle array layer 4), the one having a smaller layer thickness is usually arranged on a terminal side that does not require relatively high alignment accuracy, such as a solid electrode of a glass substrate, and the other one having a larger layer thickness is usually arranged on a terminal side that requires alignment with high positional accuracy, such as a bump of an IC chip. When only one of the second insulating resin layer 5 and the third insulating resin layer 6 is provided, a side of the film having a shorter distance to the conductive particles is arranged on a terminal side with relatively low alignment accuracy. There is no such a limitation in particular when neither of them is provided.

### (2) Method of Producing Anisotropic Conductive Film

### (2-1) Transfer Die

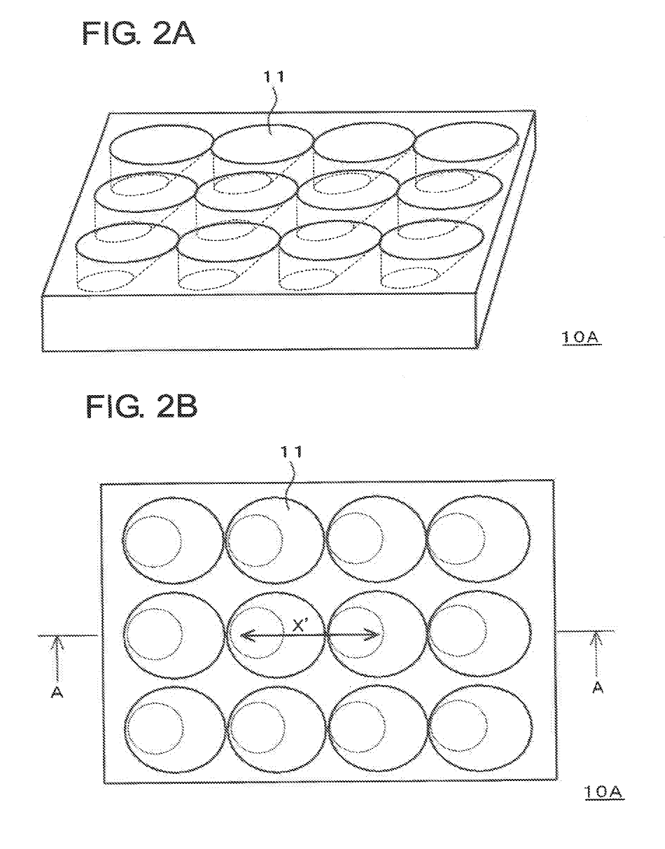

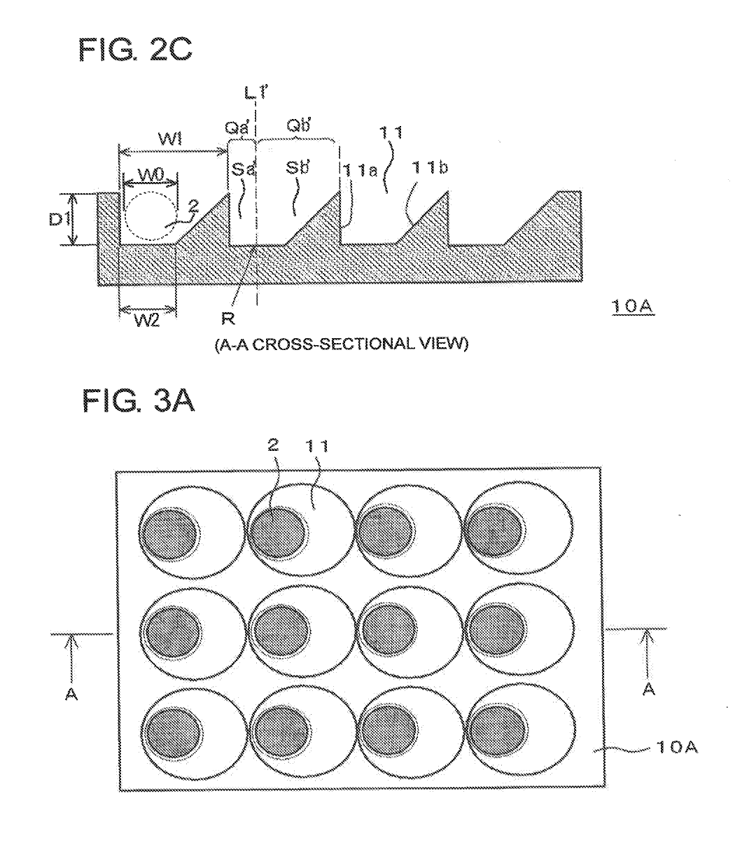

The anisotropic conductive film 1A can be produced, for example, using a transfer die as follows. Specifically, FIG. 2A is a perspective view of a transfer die 10A, which can be used for producing the anisotropic conductive film 1A, FIG. 2B is a top view of the transfer die 10A, and FIG. 2C is a cross-sectional view of the transfer die 10A.

The transfer die 10A has a plurality of openings 11 arrayed in a tetragonal lattice pattern on its surface. The transfer die 10A has a direction X′ in which a depth distribution of the individual opening 11 is asymmetric with respect to a vertical line L1′ passing through a center R of the deepest part of the opening 11. More specifically, in the cross section of the transfer die 10A (FIG. 2C) when the transfer die 10A is cut in the direction X′ passing through the center R of the deepest part of the opening 11, an area Sₐ′ of a given opening 11 on one side Qₐ′ with respect to the vertical line L1′ passing through the center R of the deepest part of the given opening 11 is smaller than an area S_{b}′ on the other side Q_{b}′.

It is noted that, in a transfer die used in the present invention, an array of openings may be appropriately selected in accordance with an array of conductive particles in an anisotropic conductive film to be produced. For example, when conductive particles are arrayed in a hexagonal lattice pattern, a transfer die having a hexagonal lattice pattern is used.

Further, regarding a shape of each opposing sidewall of the openings 11 in this cross section, a sidewall 11_{b} on the other side Q_{b}′ is inclined with respect to a sidewall 11ₐ on the one side Qₐ′. Specifically, the sidewall 11ₐ on the one side Qₐ′ is formed into a precipitous cliff shape in a thickness direction of the transfer die 10A, while the sidewall 11_{b} on the other side Q_{b}′ is inclined with respect to the thickness direction of the transfer die 10A.

Ten each of the openings 11 is filled with a single conductive particle 2, regarding a depth D1 of the openings 11, the ratio (W0/D1) of an average particle diameter W0 of the conductive particles 2 to be filled into the openings 11 and the depth D1 of the openings 11 is preferably set to 0.4 to 3.0 and more preferably 0.5 to 1.5 from the viewpoint of a balance between easiness of a work of removing the conductive particle array layer 4 formed on the transfer die 10A from the transfer die 10A and holding properties of the conductive particles 2.

In the cross section of the transfer die 10A in the direction X′ passing through the center R of the deepest part of the opening 11 (FIG. 2C), regarding a relationship between an opening diameter W1 of the openings 11 and the average particle diameter W0 of the conductive particles 2 the ratio (W1/W0) of the opening diameter W1 of the opening 11 and the average particle diameter W0 of the conductive particles 2 is preferably set to 1.2 to 5.0 and more preferably 1.5 to 3.0 from the viewpoint of easiness of filing the openings 11 with the conductive particles 2 and easiness of pressing an insulating resin into the openings 11.

Further in this cross section, regarding the relationship between a bottom diameter W2 of the opening 11 and the average particle diameter W0 of the conductive particles 2, the ratio (W2/W0) of the bottom diameter W2 of the opening 11 and the average particle diameter W0 of the conductive particles 2 is preferably set to 0 to 1.9 and more preferably 0 to 1.6 from the viewpoint of aligning a flow direction of each of the conductive particles 2 during a heating and pressurizing process.

Examples of the material for forming the transfer 10A may include inorganic materials, such as silicon, various ceramics, glasses, and metal including stainless steel, and organic materials, such as various resins. The openings 11 can be formed by a known opening-forming method, such as a photolithography method.

### (2-2) Anisotropic Conductive Film Production Method 1

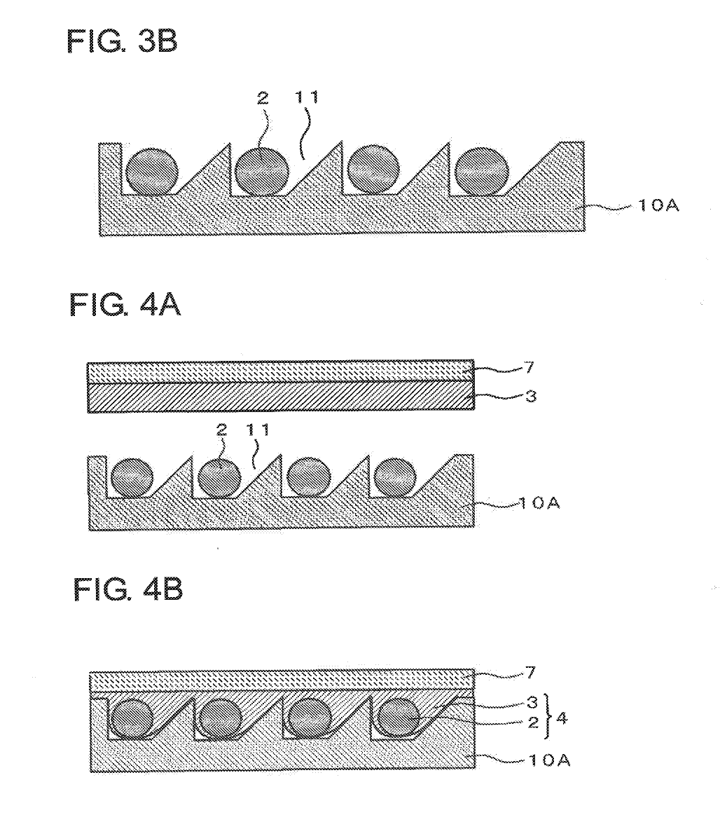

In an anisotropic conductive film production method, as shown in FIG. 3A and FIG. 3B, the conductive particles 2 are first filled into the openings 11 of the transfer die 10A. A method of filling the conductive particles 2 is not particularly limited. For example, dried conductive particles 2 or a dispersion liquid thereof dispersed in a solvent is sprayed or applied to an opening-forming face of the openings 11 of the transfer die 10A, and then the opening-forming face of the openings 11 may be wiped with a brush, a cloth, and the like. By performing the wiping operation from a bottom part to an upper part of the inclined sidewall 11_{b} along the direction X′ described above, the conductive particles 2 can be smoothly fed into the openings 11.

Further, as a method of filling the conductive particles 2, the conductive particles 2 may be first dispersed on the opening-forming face of the openings 11 of the transfer die 10A, and then transferred into the openings 11 by virtue of external force, such as a magnetic field.

Next, as shown in FIG. 4A, an insulating resin layer 3 formed on a release film 7 is allowed to face to and be laminated onto the openings 11 filled with the conductive particles 2. Then, a laminated body is pressurized to an extent that the insulating resin 3 does not enter into corners of bottom parts of the openings 11, so that, as shown in FIG. 4E, the conductive particles 2 are held in the insulating resin layer 3 such that. the conductive particles 2 are embedded in the insulating resin layer 3. When the laminated body is removed from the transfer die 10A, as shown in FIG. 4C, a conductive particle array layer 4 in which the conductive particles 2 are held in the insulating resin layer 3 while being arranged in a tetragonal lattice pattern in accordance with the array of the openings 11 of the transfer die 10A can be obtained on the release film 7.

In the conductive particle array layer 4, the conductive particles 2 may or may not be completely embedded inside the insulating resin layer 3. In order to completely embed the conductive particles 2 into the insulating resin layer 3, the conductive particles 2 in the bottom parts of the transfer die 10A can be transferred to an opening surface side of the transfer die 10A. This transfer may be carried out by external force, such as a magnetic field.

Next, as shown in FIG. 4D, it is preferable that ultraviolet (UV) rays be irradiated on an irregular surface of the conductive particle array layer 4. By this operation, the conductive particles 2 can be fixed to the insulating resin layer 3. Further, a region 3ₘ located directly below the conductive particles 2 has a relatively lower curing rate as compared to a periphery region thereof since UV irradiation is shielded by the conductive particles 2. Thus, during an anisotropic conductive connection, the conductive particles 2 are easily pushed in without causing positional displacement in a horizontal direction. As a result, the particle capturing efficiency can be improved, the conduction resistance can be decreased, and favorable conduction reliability can be achieved.

Next, as shown in FIG. 4E, the second insulating resin layer 5 is laminated onto the irregular surface of the conductive particle array layer 4 (i.e., a conductive particle 2-transferred surface of the insulating resin layer 3). Then, as shown in FIG. 4F, the release film 7 is peeled off and removed, and as shown in FIG. 4G, the third insulating resin layer 6 is laminated onto a surface, from which the release film 7 has been peeled off (i.e., an opposite surface from the conductive particle 2-transferred surface of the insulating resin layer 3). Finally, the anisotropic conductive film 1A shown in FIG. 1A, FIG. 13, and FIG. IC can be produced.

### (2-3) Anisotropic Conductive Film Production Method 2

A method of producing the anisotropic conductive film 1A shown in FIG. 1A, FIG. 1B, and FIG. 1C is not limited to the above examples. For example, in the above method, the third insulating resin layer 6 may be formed instead of the release film

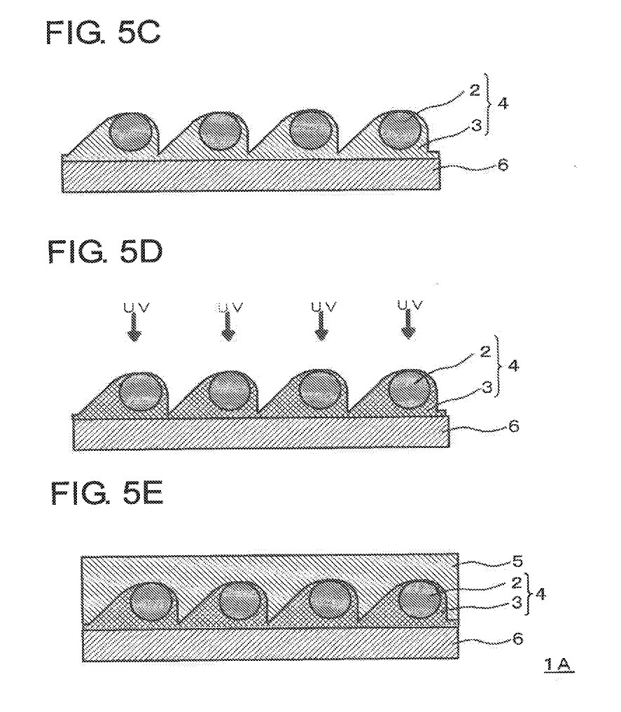

Specifically, the openings 11 of the transfer die 10A are first filled with the conductive particles 2 as shown in FIG. 3A and FIG. 3B, and then, as shown in FIG. 5A, the insulating resin layer 3, which is adhered to the third insulating resin layer 6 in advance, is allowed to face to and be laminated onto the openings 11 of the transfer 10A, the openings 11 being filled with the conductive particles 2.

Next, as shown in FIG. 5B, the conductive particle array layer 4 is formed by pressing the insulating resin 3 into the opening-forming face of the openings 11 of the transfer die 10A, thereby allowing the conductive particles 2 to be held in the insulating resin layer 3.

Subsequently, as shown in FIG. 5C, a laminated body composed of the conductive particle array layer 4 and the third insulating resin layer 6 is taken out of the transfer die 10A. Then, an irregular surface side of the insulating resin layer 3 is irradiated with UV rays to fix the conductive particles 2 to the insulating resin layer 3 as shown in FIG. 5D.

Then, the second insulating resin layer 5 is laminated onto the irregular surface of the insulating resin layer 3 as shown in FIG. 5E. Thus the anisotropic conductive film 1A shown in FIG. 1A, FIG. 1B, and FIG. 1C can be produced.

### (2-4) Anisotropic Conductive Film Production Method 3

In the method of producing the anisotropic conductive film 1A shown in FIG. 1A, FIG. 1B, and FIG. 1C, when an ultraviolet ray transmitting transfer die 10A′ is used, irradiation with ultraviolet rays to the insulating resin layer 3 holding the conductive particles ay be performed through the transfer die 10A′. The ultraviolet ray transmitting transfer die 10A′ may be formed from inorganic materials, such as ultraviolet ray transmitting glasses, and organic materials, such as polymethacrylates.

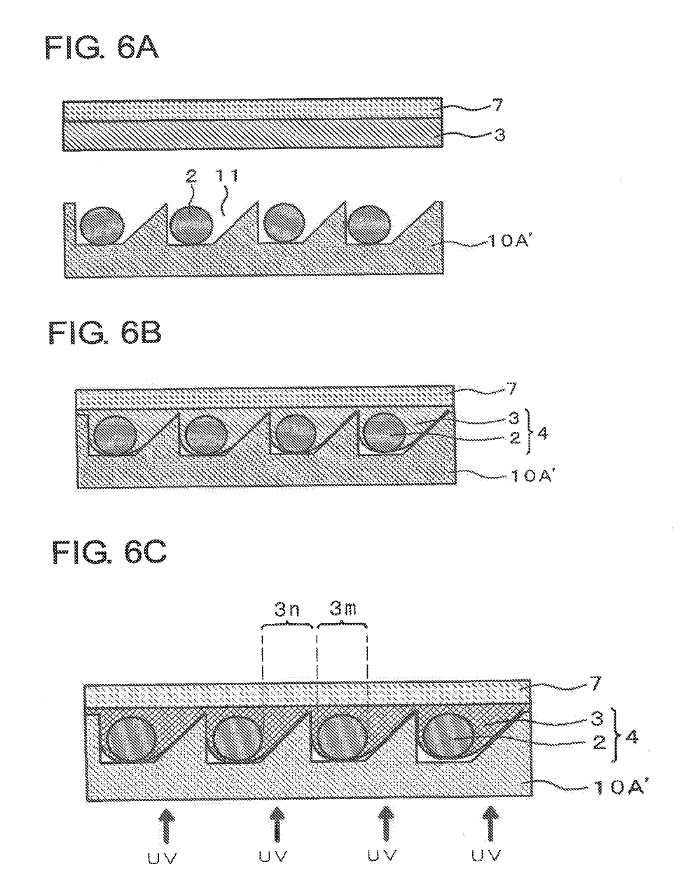

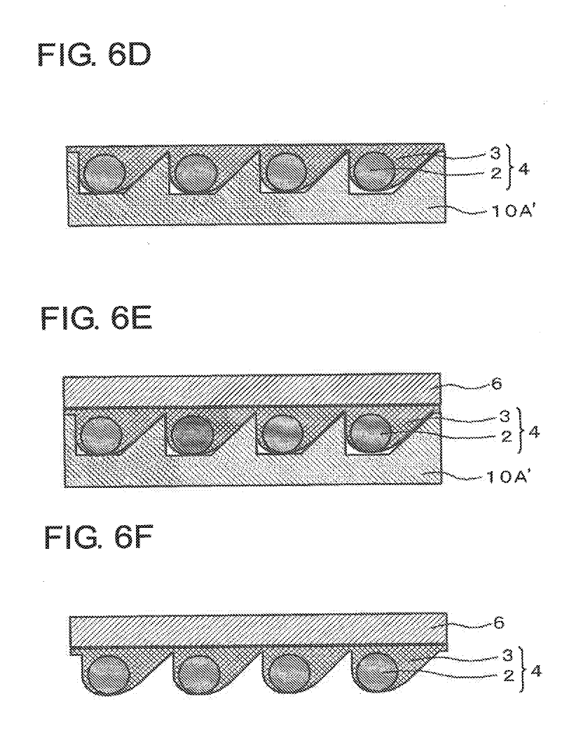

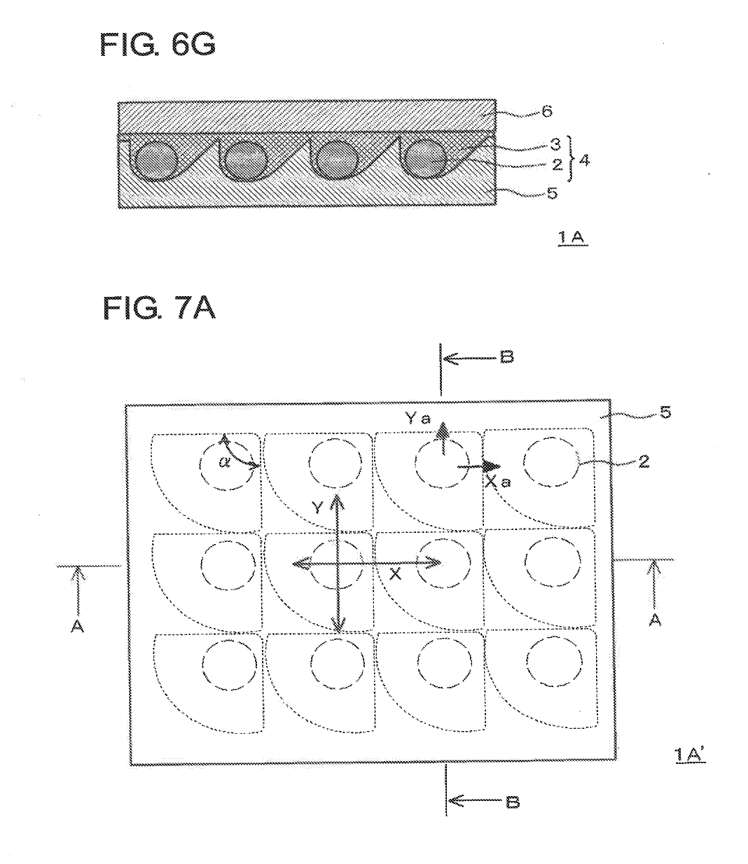

In this method, openings of the ultraviolet ray transmitting transfer die 10A′ are first filled with the conductive particles 2 as shown in FIG. 3A and FIG. 3B. Then, as shown in FIG. 6A, a photopolymerizabl.e insulating resin layer 3, formed on the release film 7, is allowed to face to and be arranged onto the openings 11 of the transfer 10A′, the openings 11 being filled with the conductive particles 2. A laminated body thus prepared is pressurized to an extent that the insulating resin layer 3 does not enter into corners of bottom parts of the openings 11, so that, as shown in FIG. 6B, the conductive particles 2 are held in the insulating resin layer 3 such that the conductive particles 2 are embedded into the insulating resin layer 3. As a result, the conductive particle array layer 4 is formed. Also in this method, the conductive particles 2 may or may not be completely embedded inside the insulating resin layer 3.

Next, as shown in FIG. 6C, ultraviolet rays are irradiated to the insulating resin layer 3 from a side of the transfer die 10A′. By the irradiation, the photopolymerizable insulating resin layer 3 can be polymerized and the conductive particles 2 can be fixed to the insulating resin layer 3. Furthermore, the curing rate of a region 3ₘ in the insulating resin layer, in which UV irradiation is shielded by the conductive particles 2, can be made relatively lower than that of a periphery region thereof, namely a region 3ₙ in the insulating resin layer. Thus, during an anisotropic conductive connection, pressing properties of the conductive particles 2 can be improved while positional displacement of the conductive particles 2 in a horizontal direction is prevented. As a result, the particle capturing efficiency can be improved, the conduction resistance can be decreased, and favorable conduction reliability can be achieved.

Next, as shown in FIG. 6D, the release film 7 is removed from the insulating resin layer 3. Then, as shown in FIG. 6E, the third insulating resin layer 6 is laminated onto a surface of the insulating resin layer 3, from which the release film 7 has been removed. A laminated body thus prepared is taken out of the transfer die 10A′ as shown in FIG. 6F, and the second insulating resin layer 5 is laminated on an irregular surface of the conductive particle array layer 4 as shown in FIG. 6G. Thus the anisotropic conductive film 1A shown in FIG. 1A, FIG. 1B, and FIG. 1C can be produced.

### (3) Modified Embodiments

(3-1) Direction in which Thickness Distribution of Insulating Resin Layer is Asymmetric Around Conductive Particles

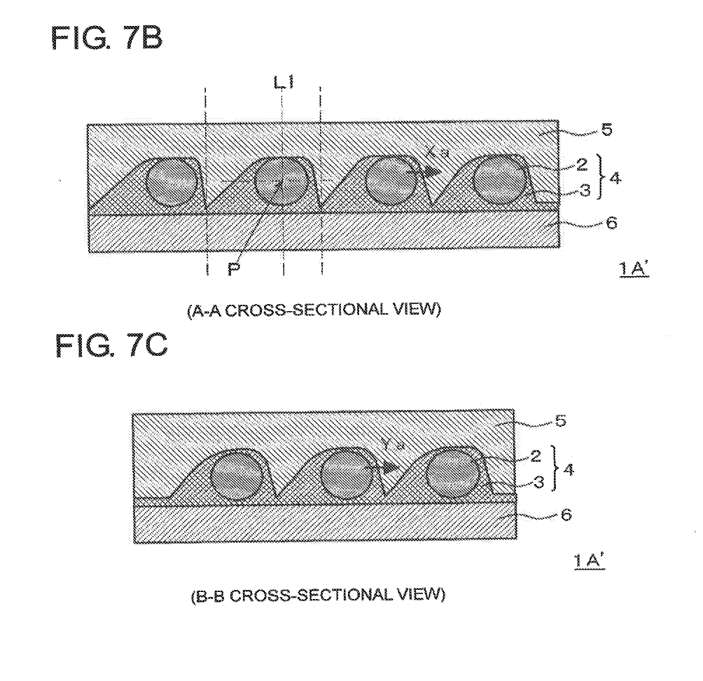

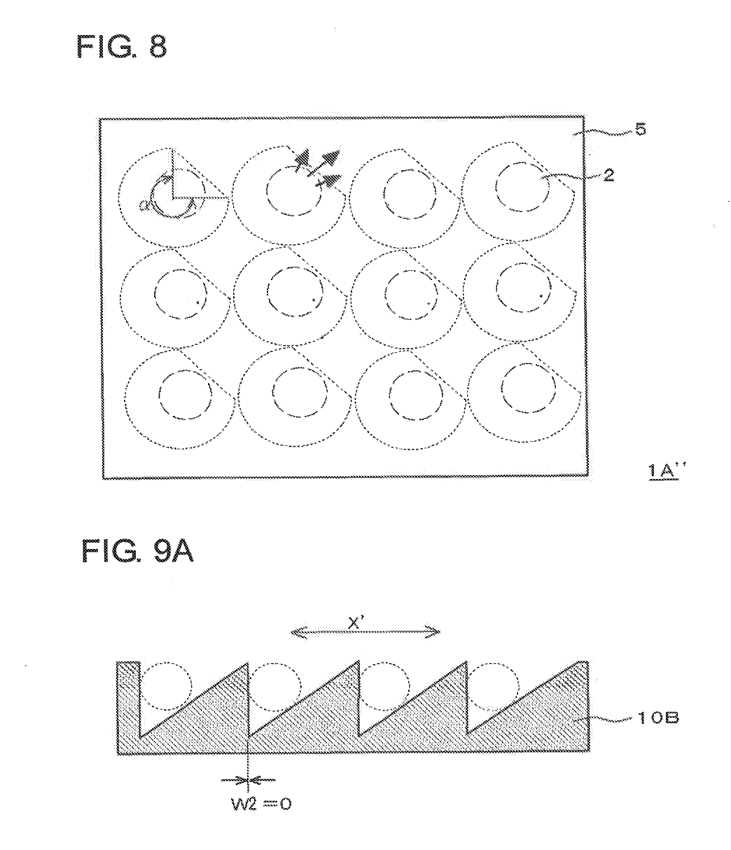

Regarding the insulating resin layer 3 directly holding the plurality of conductive particles 2 arrayed in a prescribed manner, the anisotropic conductive film of the present invention may have a plurality of directions in which a thickness distribution of the insulating resin layer 3 is asymmetric around the individual conductive particle 2 with respect to the central axis L1 of the conductive particle 2. For example, as in the anisotropic conductive film 1A′ shown in FIG. 7A, FIG. 7B, and FIG. 7C, the shape of the insulating resin layer 3 around the individual conductive particle 2 may be an approximately fan shape in a plan view. Depending on an opening angle of the fan, an asymmetry can be formed in any shape, including a fan shape with α=90° (FIG. 7A) and a semicircular shape with α=180°. Further, as shown in FIG. 8, the asymmetry may be formed in a partial circle shape consisting of a circular arc and a chord with a central angle of a (for example, α=270°).

More specifically, for example, in the anisotropic conductive film 1A′ shown in FIG. 7A, FIG. 7B, and FIG. 7C, a thickness distribution of the insulating resin layer 3 around the conductive particle 2 is asymmetric with respect to a central axis L1 of the conductive particle 2 in both X and Y directions shown in FIG. 7A. During a heating and pressurizing process when an electronic component is mounted by using the anisotropic conductive film 1A′, the conductive particles 2 easily flow to two directions Xₐ and Yₐ, having less amount of the resin holding the conductive particles 2. Thus, interconnection of the conductive particles between the electrodes caused by an irregular flow of the conductive particles by heating and pressurizing at mounting and accumulation of the conductive particles in a specific site, and conductive failure caused by the absence of the conductive particles between the electrodes can be reduced.

Further, in a case of an anisotropic conductive film 1A″ shown in FIG. 8, the conductive particles 2 easily flow in arrow directions.

In the anisotropic conductive film of the present invention, thickness distributions of the insulating resin layer 3 around the individual conductive particles 2 may be made uniform in the entire region of the anisotropic conductive film, thereby making directions in which the conductive particles 2 are likely to flow during an anisotropic conductive connection to be uniform for the every conductive particle 2. Alternatively, thickness distributions of the insulating resin layer 3 around the individual conductive particles 2 may be made different for each prescribed region of the anisotropic conductive film, thereby making directions in which the conductive particles 2 are likely to flow during an anisotropic conductive connection to be different depending on the each prescribed region of the anisotropic conductive film.

By having a direction in which a thickness distribution of the insulating resin layer 3 around the individual conductive particle 2 is asymmetric with respect to the central axis L1 of the conductive particle 2, the conductive particles 2 are likely to flow in a specific direction during an anisotropic conductive connection. Regarding this, as long as the flow directions are arranged not to overlap between the adjacent conductive particles the thickness distributions of the insulating resin layer 3 around the conductive particles 2 do not have to be made uniform in the entire region of the anisotropic conductive film.

### (3-2) Specific Shapes of Insulating Resin Layer Around Conductive Particles

In the anisotropic conductive film of the present invention, the insulating resin layer 3 may be formed in various shapes so that there is a specific direction in which a thickness distribution, around the individual conductive particle 2, of the insulating resin layer 3 holding the plurality of the conductive particles 2 arrayed in a prescribed manner is asymmetric. Thus, the transfer die used for forming the insulating resin layer 3 may also be formed in various shapes so that there is a direction X′ in which a depth distribution of the opening 11 is asymmetric with respect to the vertical line L1′ passing through the center R of the deepest part of the opening 11.

For example, in the transfer die 10A shown in FIG. 2A, FIG. 2B, and FIG. 2C, a bottom surface of the opening 11 may be formed as a rough surface having small irregularities. Having such a surface reduces a contacting area between the conductive particles 2 and the transfer die 10A, thereby facilitating an operation of detaching the conductive particle array layer from the transfer die 10A.

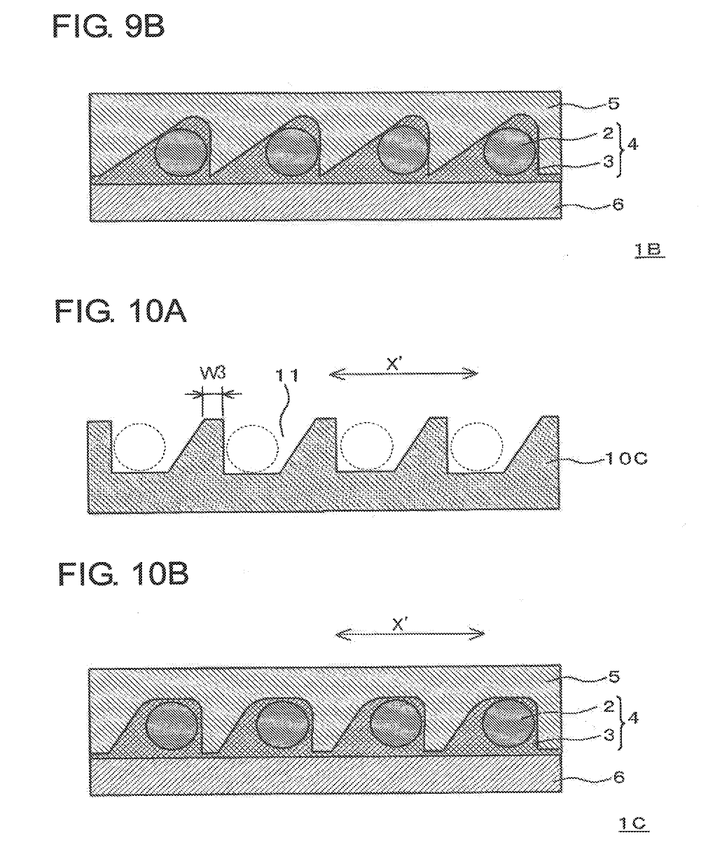

In the transfer die 10A shown in FIG. 2A, FIG. 2B, and FIG. 2C, in the cross section (FIG. 2C) obtained by cutting the transfer die 10A in the direction X′ passing through the center R of the deepest part of the opening 11, there is a prescribed width W2 on a bottom surface of the opening 11. However, as in a transfer die 10B shown in FIG. 9A, the width W2 on the bottom surface of the opening 11 may be set to zero. By using this transfer die 10B, an anisotropic conductive film 1B having a cross section shown in FIG. 9B can be obtained.

In the transfer die 10A shown in FIG. 2, FIG. and FIG. 2C, in the cross section (FIG. 2C) obtained by cutting the transfer die 10A in the direction X′ passing through the center R of the deepest part of the opening 11, the adjacent openings 11 are in contact with each other on a top surface of the transfer die 10A. However, as in a transfer die 10C shown in FIG. 10A, a prescribed distance W3 may be provided between the adjacent openings 11 on the top surface of the transfer die. By using this transfer die 10C, an anisotropic conductive film 1C having a cross section shown in FIG. 10B can be obtained.

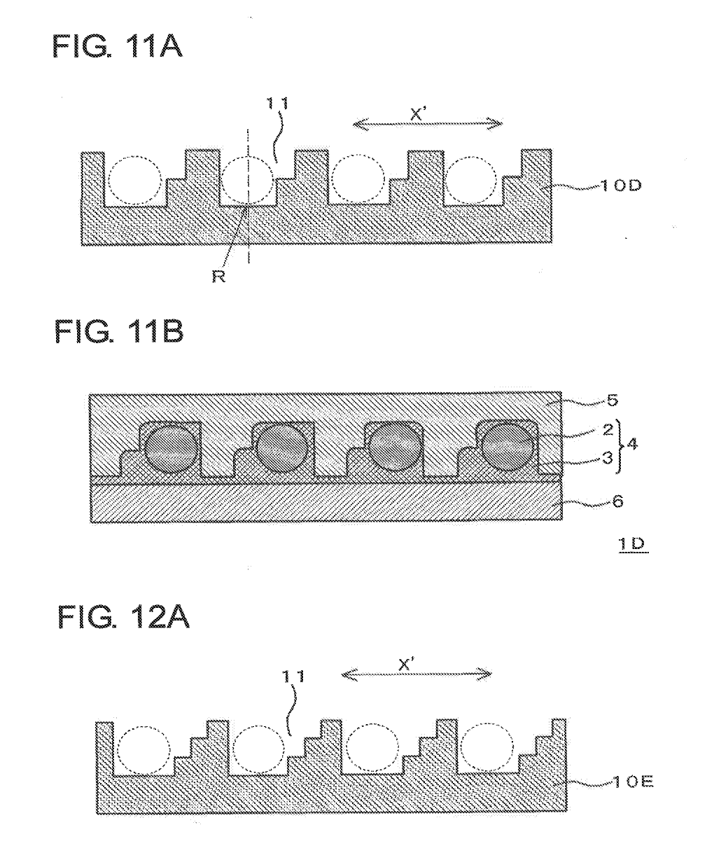

As in a transfer die 10D shown in FIG. 11A, in the cross section obtained by cutting the transfer die in the direction X′ passing through the center R of the deepest part of the opening 11, one of opposing sidewalls of the opening 11 may be formed into a precipitous cliff shape along a thickness direction of the transfer die 10D, while the other sidewall may be formed in a stepped shape. By using this transfer die 10D, an anisotropic conductive film 1D having a cross section shown in FIG. 11B can be obtained.

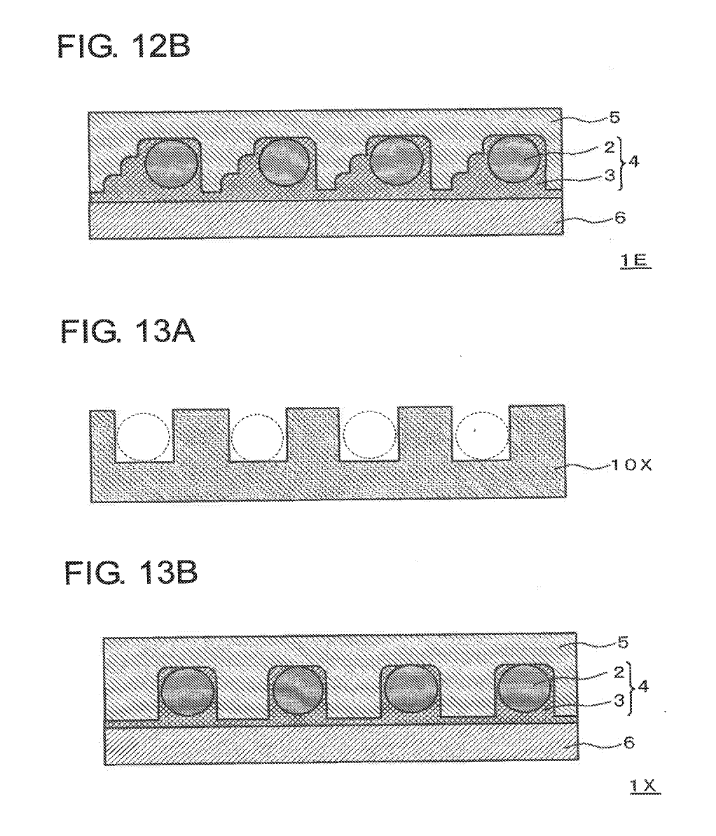

When the sidewall of the opening 11 of the transfer die is formed into a stepped shape, the number of steps may be suitably changed. For example, as in a transfer die 10E shown in FIG. 12A, the number of steps can be set to three. By using this transfer die 10E, an anisotropic conductive film 1E having a cross section shown in FIG. 12B can be obtained.

Further, in the anisotropic conductive films in the respective embodiments described above, the conductive particles 2 may be partially exposed from the insulating resin layer 3.

As a transfer die used for producing an anisotropic conductive film of the present invention, the transfer die used may have a symmetric depth distribution in the individual opening in any direction in a cross section including a vertical line passing through a center of the deepest part of the opening (for example, an entire periphery of sidewalls of the opening may be formed into a precipitous cliff shape in a thickness direction of the transfer die). In this case, by adjusting viscosity of an insulating resin that is laminated onto conductive particles filled into the openings, a pressure distribution applied to the insulating resin, irradiation timing and direction to the insulating resin, and the like, a thickness distribution of the insulating resin layer holding the conductive particles in an anisotropic conductive film may be made to be asymmetric with respect to the conductive particle.

In each of the above-mentioned anisotropic conductive films of the present invention, the conductive particles 2 are likely to flow in a specific direction during an anisotropic conductive connection. In contrast, when a transfer die 10X has openings 11, which are bilaterally symmetric in any direction as shown in FIG. 13A, an anisotropic conductive film 1X obtained using this die has such a thickness distribution, around the insulating resin layer 3 holding the conductive particles 2, that is bilaterally symmetric in any direction having the conductive particle 2 as a center, as shown in FIG. 13B. As a result, a flow direction of the conductive particles 2 is not fixed during an anisotropic conductive connection. Thus, short circuits caused by interconnection of conductive particles between the electrodes and conductive failure caused by the absence of conductive particles between the electrodes cannot be prevented from occurring.

In the present invention, the above-mentioned modified embodiments of the anisotropic conductive film can be appropriately combined.

Further, the present invention also encompasses a connection structure, in which a first electronic component and a second electronic component are connected by an anisotropic conductive connection using the anisotropic conductive film of the present invention.

### EXAMPLES

Hereinafter, the present invention will be described specifically by way of Examples.

### Examples 1 to 5 and Comparative Example 1

### (1) Production of Anisotropic Conductive Film

As a transfer die used in each Example and Comparative Example, a stainless steel transfer die having a shape and a dimension of the following (a) to (f) was prepared, and an anisotropic conductive film was produced according to the method shown in FIG. 4A to FIG. 4G.

(a) Example 1: A transfer die has the same shape as the transfer die 10A shown in FIG. 2A to FIG. 2C and a dimension shown in Table 1.
(b) Example 2: A transfer die is the transfer die 10A shown in FIG. 2A to FIG. 2C, but has a shape of the A-A cross section shown in FIG. 10A, and a dimension shown in Table 1.
(c) Example 3: A transfer die has the same shape as (b) and a dimension shown in Table 1.
(d) A transfer die is the transfer die 10A shown in FIG. 2A to FIG. 2C, but has a shape of the A-A cross section shown in FIG. 11A, and a dimension shown in Table 1.
(e) Example 5: A transfer die is the transfer die 10A shown in FIG. 2A to FIG. 2C, but has a shape of the A-A cross section shown in FIG. 12A, and a dimension shown in Table 1.
(f) Comparative Example 1: A transfer die is the transfer die 10A shown in FIG. 2A to FIG. 2C, but has a shape of the A-A cross section shown in FIG. 13A, and a dimension shown in Table 1.

To ethyl acetate or toluene, 60 parts by mass of a phenoxy resin (YP-50 available from Nippon Steel & Sumikin Chemical Co., Ltd), 40 parts by mass of an acrylate (EB-600 available from Daicel-Allnex Ltd.), and 2 parts by mass of a photo-radical polymerization initiator (IRGACURE 369, available from BASF Japan Ltd.) were added to prepare a liquid mixture having a solid content of 50% by mass. In parallel, a polyethylene terephthalate film (PET film) having a thickness of 50 μm was prepared as a release film. The liquid mixture was applied to the release film in a dry thickness of 5 μm, and the applied film was dried in an oven at 80° C. for 5 min to form a photo-radical polymerizable insulating resin layer.

Next, conductive particles with an average particle diameter of 3 μm (Ni/Au plated resin particles, AUL 703, available from Sekisui Chemical Co., Ltd.) were dispersed in a solvent and the resulting dispersion was applied to each of the openings of the transfer dies shown in Table 1. The openings were then filled with the conductive particles by wiping with a cloth (FIG. 4A).

Next, the insulating resin layer mentioned above was arranged so as to face to an opening-forming face of the transfer die. The conductive particles were pressed into the insulating resin layer by applying pressure under conditions of 60° C. and 0.5 MPa from a side of the release film. Thus, a conductive particle array layer 4, in which the conductive particles 2 were held in the insulating resin layer 3, was formed (FIG. 4B).

Subsequently, the conductive particle array layer 4 was taken out of the transfer die 10A (FIG. 4C), and then the insulating resin layer 3 was irradiated on a surface having irregularities with ultraviolet rays with a wavelength of 365 nm and an integrated light quantity of 4,000 mJ/cm². Thus the conductive particles 2 were fixed to the insulating resin layer 3 (FIG. 4D).

To ethyl acetate or toluene, 60 parts by mass of a phenoxy resin (YP-50 available from Nippon Steel & Sumikin Chemical Co., Ltd), 40 parts by mass of an epoxy resin (iER828 available from Mitsubishi Chemical Corp.), and 2 parts by mass of a thermal-cationic polymerization initiator (SI-60L available from Sanshin Chemical Industry) were added to prepare a liquid mixture having a solid content of 50% by mass. The liquid mixture was applied to a PET film having a thickness of 50 μm so as to have a dry thickness of 12 μm, and the applied film was dried in an oven at 80° C. for 5 min to form a second insulating resin layer S. The similar operation was performed to form a third insulating resin layer 6 having a dry thickness of 3 μm.

As mentioned above, the conductive particle array layer 4 included the insulating resin layer 3 having the conductive particles 2 fixed thereto. On a side of the insulating resin layer 3 of the conductive particle array layer 4, the second insulating resin layer 5 was laminated under conditions of 60° C. and 0.5 MPa (FIG. 4E). Then the release film 7 was removed from the other side (FIG. 4F). The third insulating resin layer 6 was laminated on the surface, from which the release film 7 had been removed, in a similar manner as the second insulating resin layer to obtain an anisotropic conductive film (FIG. 4G).

### (2) Evaluation

The anisotropic conductive films obtained from the respective Examples and Comparative Example were evaluated for (i) bonding strength, (ii) the number of interconnected conductive particles, and (iii) insulating properties (a rate of occurrence of short circuits) as follows. The results were shown in Table 1.

### (i) Bonding Strength

Using the anisotropic conductive films obtained from the respective Examples and Comparative Example, a mounted sample was produced by heating and pressurizing a member for conduction performance evaluation under conditions of 180° C. and 80 MPa for 5 sec, the member being composed of an IC and a glass substrate.

IC: Dimensions of 1.8×20.0 mm, thickness of 0.5 mm, bump size of 30×85 μm, bump height of 15 μm, and bump pitch of 50 μm

Glass substrate: available from Corning Inc., 1737F, size of 50×30 mm, and thickness of 0.5 mm

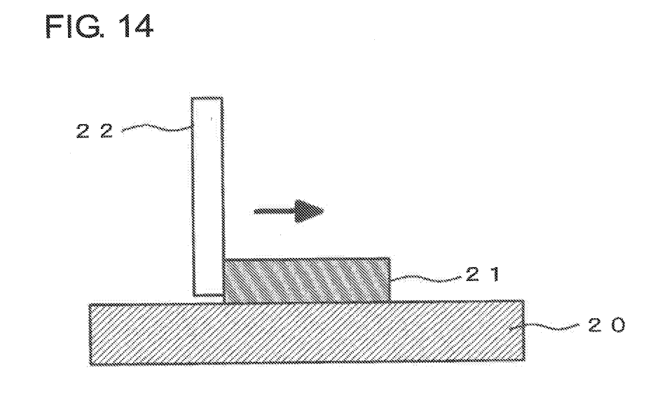

Next, as shown in FIG. 14, using a bond tester available from Dage Japan Co., Ltd, a probe 22 was brought into contact with an IC 21 located on a glass substrate 20 and shearing force was applied to the probe 22 in a direction of an arrow. Then, a force required for peeling the IC 21 was measured.

### (ii) Number of Interconnected Conductive Particles

A connection region (excluding a connection part between terminals) of the mounted sample was examined by a microscope and a maximum number of interconnected conductive particles in an area of 40,000 μm²was counted.

(iii) Insulating Properties

Using the anisotropic conductive films obtained from the respective Examples and Comparative Example, a short circuit occurrence rate was determined under a connection condition similar to by mutually connecting a comb-teeth TEG (test element group) pattern at an interval of 7.5 μm. For practical use, the rate is desirably 100 ppm or less. The short circuit occurrence rate can be calculated by “number of short circuit occurrence/total number of 7.5 μm intervals.”

As seen from Table 1, it was found that the anisotropic conductive films of Examples 1 to 5 have significantly smaller numbers of interconnected conductive particles and lower short circuit occurrence rates, as compared to the anisotropic conductive film of Comparative Examples 1. Further, the anisotropic conductive films of Examples 1 to 5 have better bond strength as compared to the anisotropic conductive film of Comparative Examples 1. This is because, it is speculated that in the anisotropic conductive films of Examples 1 to 5, a thickness distribution of the insulating resin layer directly holding the conductive particles is asymmetric with respect to the conductive particles, and thus an irregularity of the insulating resin layer may have an influence on an irregular surface of the anisotropic conductive film, thereby increasing adhesive properties of the resin.

### INDUSTRIAL APPLICABILITY

The present invention is useful as a technique for connecting electronic components, such as an IC chip, with a wiring board via an anisotropic conductive connection.

### REFERENCE SIGNS LIST

1A, 1A′, 1A″, 1B, 1C, 1D, 1E, 1X anisotropic conductive film

2 conductive particle

3 insulating resin layer

3ₐ, 3_{b} side surface

3ₘ, 3ₙ region

4 conductive particle array layer

5 second insulating resin layer

6 third insulating resin layer

7 release film

10A, 10A′, 10B, 10C, 10D, 10E, 10X transfer die

11 opening

11ₐ, 11_{b} sidewall of opening

20 glass substrate

21 IC

22 probe

D1 depth of opening

L1 central axis of conductive particle

L1′ vertical line passing through center of deepest part of opening of transfer die

P center of conductive particle

Q region surrounding conductive particle

Qₐ one side surface of conductive particle

Q_{b} the other side surface of conductive particle

R center of deepest part of opening of transfer die

Sₐ, Sₐ′, S_{b}, S_{b}′ area

W0 average particle diameter of conductive particles

W1 opening diameter of opening

W3 distance between openings

X, Xₐ, X′, Y, Yₐ direction

1. An anisotropic conductive film comprising:
a conductive particle array layer in which a plurality of conductive particles are arrayed in a prescribed manner and held in an insulating resin layer,
wherein the anisotropic conductive film has a resin amount distribution, around the individual conductive particle, of the insulating resin layer holding the array of the conductive particles, and the resin amount distribution has a direction in which a resin amount decreases.

2. The anisotropic conductive film according to claim 1, wherein, in a film surface direction, the resin amount distribution, around the individual conductive particle, of the insulating resin layer holding the array of the conductive particles has a direction in which a resin amount decreases.

3. The anisotropic conductive film according to claim 1, wherein the direction in which the resin amount is less aligned in the same direction in the plurality of conductive particles.

4. The anisotropic conductive film according to claim 1, wherein in a cross section of the anisotropic conductive film when the anisotropic conductive film is cut in the direction in which the resin amount decreases, the direction passing through a center of the conductive particle, an area of the insulating resin layer surrounding the conductive particle is configured such that an area on one side of the conductive particle is smaller than an area on the other side.

5. The anisotropic conductive film according to claim 4, wherein in the cross section of the anisotropic conductive film when the anisotropic conductive film is cut in the direction in which the resin amount decreases, the direction passing through the center of the conductive particle, one side surface of the insulating resin layer surrounding the conductive particle is formed into a precipitous cliff shape in a thickness direction of the anisotropic conductive and the other side surface thereof is inclined with respect to the thickness direction of the anisotropic conductive film more than the one side surface.

6. The anisotropic conductive film according to claim 4, wherein in the cross section of the anisotropic conductive film when the anisotropic conductive film is cut in the direction in which the resin amount decreases, the direction passing through the center of the conductive particle, one side surface of the insulating resin layer surrounding the conductive particle is formed into a precipitous cliff shape in a thickness direction of the anisotropic conductive film, and the other side surface thereof is formed into a stepped shape.

7. The anisotropic conductive film according to claim 1, wherein the conductive particle array layer has a flat surface on one side and an irregular surface on the other side, and a second insulating resin layer is laminated on the irregular surface.

8. The anisotropic conductive film according to claim 7, wherein a third insulating resin layer is laminated on the flat surface.

9. A method of producing the anisotropic conductive film according to claim 1, comprising the steps of:
filling a transfer die having a plurality of openings on a surface thereof with conductive particles;
laminating an insulating resin on the conductive particles; and
forming a conductive particle array layer, in which a plurality of the conductive particles are arrayed in a prescribed manner and held in an insulating resin layer, the conductive particle array layer being transferred from the transfer die to the insulating resin layer,
wherein the transfer die used ensures that a depth distribution in an individual opening is formed so as to generate a direction in which the resin amount decreases, where the depth distribution regulates a resin amount around the conductive particles in the insulating resin layer.

10. The production method according to claim 9, wherein in a cross section of the transfer die when the transfer die is cut in the direction in which the resin amount decreases, the direction passing through the center of the deepest part of the opening, an area of the opening on one side with respect to the vertical line passing through the center of the deepest part of the opening is smaller than an area on the other side.

11. The production method according to claim 9 wherein when the transfer die is cut in the direction in which the resin amount decreases, the direction passing through the center of the deepest part of the opening, one of opposing sidewalls of the opening is formed into a precipitous cliff shape in a thickness direction of the transfer die, and the other opposing sidewall is inclined with respect to the thickness direction of the anisotropic conductive film more than the one opposing sidewall.

12. The production method according to claim 9, wherein when the transfer die is cut in the direction in which the resin amount decreases, the direction passing through the center of the deep deepest part of the opening, one of opposing sidewalls of the opening is formed into a precipitous cliff shape in a thickness direction of the transfer die, and the other opposing sidewall is formed in a stepped shape.

13. The production method according to claim 9, wherein in the step of forming a conductive particle array layer, the insulating resin layer is polymerized.

14. The production method according to claim 9, wherein the insulating resin used is a photo-radical polymerizable resin, and the insulating resin laminated onto the conductive particles is polymerized by irradiation with ultraviolet rays.

15. The production method according to any one of claim 9, wherein a second insulating resin layer is laminated onto a conductive particle-transferred surface of the insulating resin layer.

16. The production method according to claim 15, wherein a third insulating resin layer is laminated onto an opposite surface from the conductive particle-transferred surface of the insulating resin layer.

17. A connection structure connecting a first electronic component and a second electronic component via an anisotropic conductive connection using the anisotropic conductive film according to claim 1.

18. A method of producing a connection structure connecting a first electronic component and a second electronic component via an anisotropic conductive connection using the anisotropic conductive film according to claim 1, comprising:
connecting a first electronic, component and a second electronic component via an anisotropic conductive connection using the anisotropic conductive fil
